(19) United States
(12) Patent Application Publication
(10) Pub. No.: US 2007/0007672 A1
(43) Pub. Date: Jan. 11, 2007

(54) Package film, package of electrode member, and stand for package

(76) Inventors: Satoshi Goishihara, Tokyo (JP); Kei Hasegawa, Tokyo (JP)

Correspondence Address: BIRCH STEWART KOLASCH & BIRCH, PO BOX 747, FALLS CHURCH, VA, 22040-0747, US

(21) Appl. No.: 10/574,008

(22) PCT Filed: Sep. 29, 2004
(86) PCT No.: PCT/JP04/14252

§ 371 Date: Mar. 29, 2006

(30) Foreign Application Priority Data
Sep. 30, 2003 (JP) 2003-341449
Jun. 11, 2004 (JP) 2004-174105

(51) Int. Cl. H01L 23/29

(52) U.S. Cl. 257/790

(57) ABSTRACT

The present invention provides an electrode material package, by which the electrode materials are protected from damages due to external impacts, etc. during the transportation or storage. Further, with the electrode material package of the present invention, the electrode material can be kept under a low humidity atmosphere, and the term over which the quality of the electrode material is guaranteed can be prolonged. The electrode material package 20 has a roll of the electrode material 1 wound onto a winding core 2; a pair of flanges 21, of which the side faces 21a have larger dimensions than the roll of the electrode material 1, holding both sides of the roll of the electrode material 1 through a pair of cushion materials 22; and a bag 19 made of a package film 10. The package film 10 of the bag 19 includes a moisture proof layer 12 of an aluminum foil and an intermediate layer 13 of an oriented nylon, which is located inside of the moisture proof layer 12 and faces the electrode material 1.

### TECHNICAL FIELD

The present invention relates to a package film for packaging an electrode material used in a battery or the like, and to an electrode material package for use in transporting or storing the electrode material.

### BACKGROUND OF THE INVENTION

Under the current trend of the manufacture at the most effective area, when batteries are manufactured, firstly electrode materials are domestically manufactured, and then are transported to a foreign country where the production costs are lower, and where the electrode materials are cut and wound to be assembled into battery packages.

Since such the electrode materials undergo coating and rolling process during manufacturing, they are usually provided in a form of roll, wound onto a winding core of aluminum or the like. Then, such the rolls of the electrode materials are slit into desired width, and packaged.

Since the electrode materials are weak to moisture, they are packaged in the package films having the moisture proof nature, during transporting or storing. Such the moisture proof package films are needed in a variety of fields, not only in the electrode materials fields. Therefore, several kinds of the package films have been developed (e.g. Patent Literatures 1 and 2).

Patent Literature 1: JP-A-2000-25147

Patent Literature 2: JP-A-H8-336926

### DISCLOSURE OF THE INVENTION

Problems to be Solved by the Invention

The package film disclosed in Patent Literature 1 is mainly used to package the foods and beverages such as confectionery, etc. distributed to general consumers. The package film disclosed in Patent Literature 2 is mainly used to package the relatively lightweight products such as parenteral solutions, etc.

Thus, the package films disclosed in Patent Literatures 1 and 2 are superior in view of preventing pin holes from occurring on the outer surfaces thereof. But, the package films are not provided with any means to prevent pin holes from occurring on the inner surfaces.

Meanwhile, the electrode materials are industrial products, which are handled by skilled persons, and therefore, the pin holes scarcely occurs on the outer surfaces of package films. However, the electrode materials are heavy and subjected to long distance transport, and therefore, pin holes may occur on the inner surfaces of the package films, because of the friction between the electrode materials and the inner surfaces of the package films.

The friction between the electrode materials and the package films may cause the pin holes, and also may cause the loosing of rolls of electrode materials or lateral slip in the wound layers of electrode materials in the rolls. Therefore, it is needed to improve the form of the electrode material, at before packaged in the package film.

The present invention is completed in order to solve these problems. An object of the present invention is to provide a moisture proof package film, capable of preventing pin holes from occurring on its inner surface due to the friction between the package film and the packaged electrode material during the transportation or storage. Another object of the present invention is to provide an electrode material package, with which the electrode material can be protected from damage due to external impacts or the like, the electrode material can be kept in a low humidity condition, and thus, the term over which the quality of the electrode material is guaranteed can be prolonged.

Means for Solving the Problems

The present invention provides a package film for packaging an electrode material, characterized in that the package film comprises:

a moisture proof layer of an aluminum foil, and an intermediate layer of an oriented nylon, which is located inside of the moisture proof layer and faces the electrode material.

The present invention provides a package film, further comprising an outermost layer of PET and an innermost layer of LLD-PEF.

The present invention provides an electrode material package, characterized in that it comprises:

a roll of an electrode material which is wound onto a winding core,

a pair of flanges which hold both sides of the roll of the electrode material through a pair of cushion materials, and which have a side face larger than a contour of the roll of the electrode material, and

a package film which packages the roll of the electrode material,

the package film comprising a moisture proof layer of an aluminum foil, and an intermediate layer of an oriented nylon, which is located inside of the moisture proof layer and faces the electrode material.

The present invention provides an electrode material package, characterized in that:

the winding core, on which the roll of the electrode material is wound, is secured to the flange with screws, so that the pair of flanges hold the roll of the electrode material.

The present invention provides an electrode material package, characterized in that:

the winding core, on which the roll of the electrode material is wound, is projected from the roll of the electrode material to pass through the flange, and

the projected portion of the winding core is provided with an outer thread, with which a stopper ring is engaged, so that the pair of flanges hold the roll of the electrode material.

The present invention provides an electrode material package, characterized in that:

the winding core, on which the roll of the electrode material is wound, has a center hole extending along its longitudinal axis,

a pair of core caps are provided on outer sides of the pair of flanges, each of the core caps passing through the flange to engage with the center hole of the winding core, and

each of the core caps is engaged into the center hole of the winding core through the flange, so that the pair of flanges hold the roll of the electrode material.

The present invention provides an electrode material package, characterized in that it comprises:

a plurality of rolls of electrode materials, each of which is wound onto a winding core,

cushion materials, each of which is interposed between the rolls of the electrode materials,

a skid shaft which passes through the winding cores, on each of which the roll of the electrode material is wound, and the cushion materials to thereby support them thereon, and

a moisture proof casing, which encloses the rolls of the electrode materials and the cushion materials, and is removably attached to the skid shaft.

The present invention provides an electrode material package of claim 7, further comprising:

a pair of flanges which hold the rolls of the electrodes and the cushion materials, and each of which has a larger side face than a contour of the roll of the electrode material.

The present invention provides an electrode material package of claim 7, characterized in that:

one end portion of the skid shaft is enclosed in the casing, and the other end portion of the skid shaft is projected out of the casing,

the one end portion of the skid shaft is engaged with a stopper ring, and the other end portion of the skid shaft is provided with a flange portion, so that the rolls of the electrode materials are held between the flange portion of the skid shaft and the stopper ring.

The present invention provides an electrode material package of claim 7, characterized in that:

the casing comprises a casing body and a lid fixed to the skid shaft.

The present invention provides an electrode material package of claim 8, characterized in that:

the casing comprises a casing body and a lid fixed to the skid shaft, and

the lid functions as one of the pair of the flanges.

### EFFECT OF THE INVENTION

According to the present invention, the occurrence of pin holes on the inner surface of a package film due to the friction or impacts between the package film and the packaged electrode material can be prevented, so that the packaged electrode material can be kept under a low humidity condition.

Further, according to the present invention, the quality of an electrode material can be guaranteed over a longer lasting period of time, because the electrode material packaged in the package film can be protected from damages due to external impacts and also can be kept under a low humidity condition.

### BRIEF DESCRIPTION OF THE DRAWINGS

FIG. 1 is a partial sectional view of a package film according to the first embodiment of the present invention, schematically illustrating the lamination structure of the packaging film.

FIG. 2 is a perspective view of a bag made of the package film.

FIG. 3 is a perspective view of an electrode material package according to the present invention.

FIG. 4 is a front view, illustrating how the cushion materials and the flanges are attached to the electrode material.

FIG. 5 is a front view, illustrating how the cushion materials and the flanges are attached to the electrode material, according to the first modification of the first embodiment of the present invention.

FIG. 6 is an exploded perspective view, illustrating how the cushion materials and the flanges are attached to the electrode material, according to the second modification of the first embodiment of the present invention.

FIG. 7 is a front view of an electrode material package according to the second embodiment of the present invention.

FIG. 8 is a front view, showing of a practical application of the second embodiment of the present invention.

FIG. 9 is a perspective view of a roll of the electrode material.

FIG. 10 is a diagram illustrating the principle to prevent a lateral slip of the wound layers of the electrode material in the roll, according to the third embodiment of the present invention.

FIG. 11 shows a diagram illustrating one of the rolls of materials to be included in the package shown in FIG. 10.

FIG. 12 shows a diagram illustrating the cushion materials used in the package shown in FIG. 10.

FIG. 13 shows a diagram illustrating a connection ring used in the third embodiment.

### BEST MODES FOR CARRYING OUT THE INVENTION

### First Embodiment

Hereinafter, embodiments of a package film for packaging an electrode material, and an electrode material package according to the present invention will be described with reference to the accompanying drawings.

[Electrode Material]

First, an electrode material 1 to be packaged according to the present invention is described with reference to FIG. 9, which shows a perspective view of the electrode material 1.

The electrode material 1 is used in secondary batteries, particularly lithium ion secondary batteries, double layer capacitors and fuel batteries. The electrode material 1 is cut and wound to be assembled into a battery package. In manufacture, the electrode material 1 is usually provided in a form of roll, wound onto a winding core 2 of aluminum or the like, after being subjected to a coating process and a rolling process. Such the roll of the electrode material 1 is cut into a desired width, and then to be packaged. One roll of the electrode material 1 weighs about 20 kg.

The electrode material 1 is weak to moisture. If the electrode material 1 is placed under a high humidity atmosphere, the performance of a battery of the final product would markedly degrade.

[Package Film]

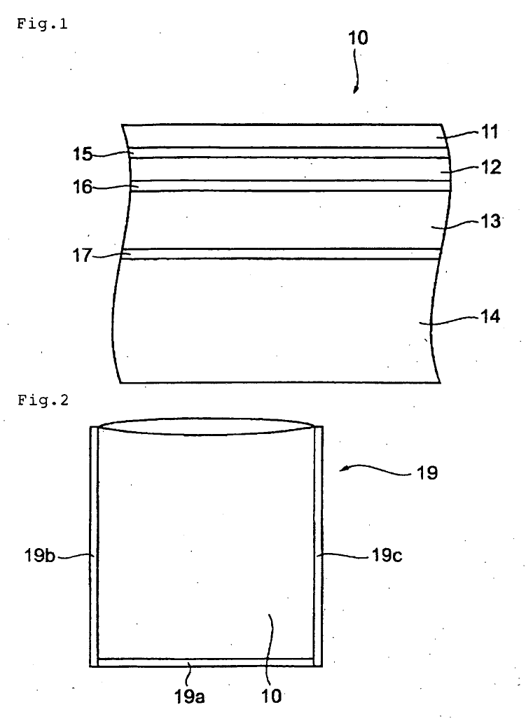

Next, a package film 10 for packaging the electrode material 1 is described. FIG. 1 shows a partial sectional view of the package film 10 of the present invention, schematically illustrating the layer structure of the film 10.

As shown in FIG. 1, the package film 10 comprises an innermost layer 14 which faces the packaged electrode material 1, an intermediate layer 13 laminated on the innermost layer 14 with an adhesive layer 17 therebetween, a moisture proof layer 12 laminated on the intermediate layer 13 with an adhesive layer 16 therebetween, and an outermost layer 11 laminated on the moisture proof layer 12 with an adhesive layer 15 therebetween. The outermost layer 11 locates farthest from the electrode material 1.

The innermost layer 14 is made of a material which can be melted by heating for bonding, such that the resultant package film 10 can be formed into a bag 19. Specific examples of such the material include low-density polyethylene, medium-density polyethylene, high-density polyethylene, polypropylene and the like. In the shown embodiment, LLD-PEF (linear low-density polyethylene) is used, in view of adhesive strength, manufacturing cost, and so on.

The thickness of the innermost layer 14 is preferably 20 to 200 μm, which makes it possible to ensure a sufficient adhesive strength for the resultant package film, for packaging the heavy electrode material 1. In the shown embodiment, the thickness of the innermost layer 14 is 80 μm.

Next, the intermediate layer 13 is described. The intermediate layer 13 is intended to protect the moisture proof layer 12, so as not to be damaged from inside of the package film 10 due to the friction or impacts between the package film 10 and the electrode material 1, when the heavy and thick electrode material 1 is packaged in the package film 10. Therefore, the intermediate layer 13 is made of an oriented nylon, which has flexibility and extensibility to absorb the impacts applied from the electrode material 1 to the moisture proof layer 12. The thickness of the intermediate layer 13 is preferably 10 to 100 μm, in order to sufficiently absorb the impacts applied to the moisture proof layer 12 from the electrode material 1. In the shown embodiment, the thickness of the intermediate layer 13 is 30 μm.

Next, the moisture proof layer 12 is described. The moisture proof layer 12 is intended to allow the resultant package film 10 to have moisture barrier properties, and is made of an aluminum foil. The thickness of the aluminum foil is preferably 3 to 25 μm in order to ensure sufficient moisture barrier properties. In the shown embodiment, the thickness of the aluminum foil is 9 μm.

Next, the outermost layer 11 is described. The outermost layer 11 is intended to protect the moisture proof layer 12 from the external frictions or impacts, and this layer may be made of polyethylene, polypropylene, polyethylenenaphthalate or the like. However, differently from bags for confectionery handled by many and unspecified consumers, the electrode material 1 is handled by specific and skilled persons, and therefore, external influence is not needed to be severely taken into consideration. In the shown embodiment, the outermost layer 11 is preferably formed of PET (polyethylene-terephthalate), in consideration of the production cost and the productivity as being the most important factors.

Preferably, the thickness of the outermost layer 11 is 5 to 100 μm, in most consideration of the production cost and the productivity. In the shown embodiment, the thickness of the outermost layer 11 is 12 μm.

Between each of the above layers 11, 12, 13 and 14, the adhesive layers 15, 16 and 17 are respectively interposed to adhere the layers 11, 12, 13 and 14. There is no particular limit in selection of an adhesive used to form the adhesive layers 15, 16 and 17, in so far as the layers 11, 12, 13 and 14 can be adhered with such an adhesive. In the shown embodiment, an urethane-isocyanate-based resin is preferably used as the adhesive in view of its adhesive strength, because the heavy electrode material 1 is to be packaged.

Next, a method for manufacturing the package film 10 from the outermost layer 11, the moisture proof layer 12, the intermediate layer 13 and the innermost layer 14 is described. As the method for manufacturing the package film 10 by adhering these layers to one another, any of the general lamination methods can be employed, such as wet lamination, dry lamination, extrusion lamination, etc. In the shown embodiment, the package film 10 is manufactured by the dry lamination method in consideration of the adhesive strength, because the heavy electrode material 1 is to be packaged.

[Electrode Material Package]

Next, an electrode material package is described, which is made by packaging the electrode material 1 in a bag 19 made of the package film 10.

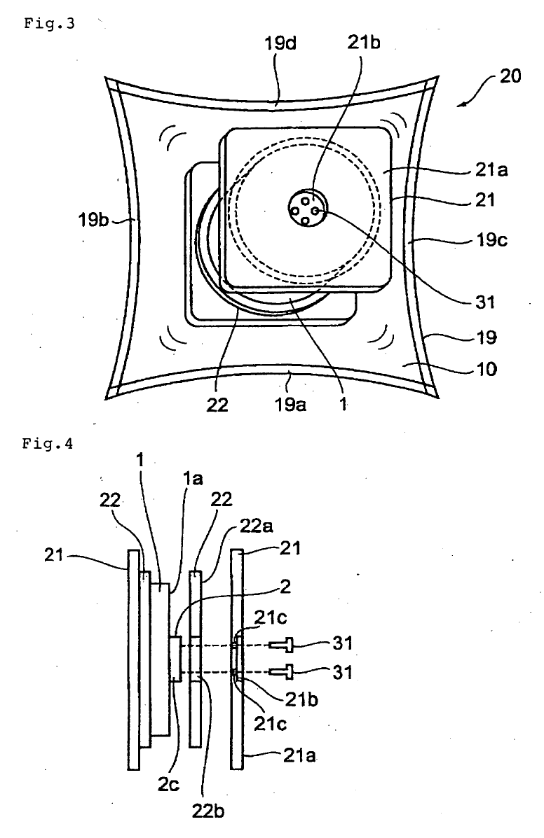

FIG. 3 shows the perspective view of an electrode material package 20 according to the present invention. As shown in FIG. 3, the package 20 comprises a roll of an electrode material 1 wound onto a winding core 2, a pair of flanges 21 holding the electrode material 1 therebetween through a pair of cushion materials 22, and the bag 19 made of the package film 10, which packages the electrode material 1 therein.

The package film used in this embodiment is the same one as the package film 10 in FIGS. 1 and 2. Thus, the like parts or components are denoted by the like reference numerals also in this embodiment, to thereby skip the detailed descriptions thereof.

FIG. 4 shows a front view, illustrating how the cushion materials 22 and the flanges 21 are attached to the electrode material 1. As shown in FIG. 4, the winding core 2, on which the electrode material 1 is wound, has a pair of cylindrical projections 2c which are projected beyond the width of the roll of the electrode material 1.

The pair of cushion materials 22 are disposed outsides of the electrode material 1. Each of the cushion materials 22 is formed in the shape of a disc plate, which has an outer diameter larger than that of the roll of the electrode material 1. The cushion materials 22 is provided with a through hole 22b, at its center, having an inner diameter substantially equal to the outer diameter of the cylindrical projection 2c of the winding core 2. The cylindrical projection 2c penetrates this through hole 22b. Each of the cushion materials 22 is formed of, for example foamed polyethylene, and is intended to protect the side face of the roll of the electrode material 1.

As described above, the pair of the flanges 21 are disposed at outsides of the electrode material 1, and hold the electrode material 1 with the pair of the cushion materials 22 therebetween. Each of the flanges 21 is formed in the shape of a flat rectangular plate rounded at its four corners. The flanges 21 have a side face 21a which is larger than the contour of the side face la of the roll of the electrode material 1. Thus, when the pair of the flanges 21 are disposed at outsides of the roll of the electrode material 1, the overall side faces 1a of the roll of the electrode material 1 are covered by the flanges 21. The flanges 21 are made of aluminum plates or polypropylene plates, for example.

Each of the flanges 21 has four holes 21c at near the center. Screws 31 are passed through the holes 21c from the outer side face 21a of the flange 21 and are engaged with the corresponding threaded holes (not shown) formed on the projection 21c of the winding core 2. Thus, the pair of the flanges 21 are secured to the winding core 2, to thereby firmly hold the electrode material 1 with the pair of cushion materials 22 therebetween.

To prevent the heads of the screws 31 from projecting beyond the side face 21a of the flange 21, it is preferable to form a concavity 21b around the holes 21c of the flange 21 (see FIGS. 3 and 4).

The electrode material package 20 is obtained by packaging the electrode material 1 held between the flanges 21 as above, into the bag 19 made of the package film 10 (see FIG. 3).

Here, the manner of packaging by the bag 19 is described. The bag 19 is made as follows. Firstly, two sheet of the rectangular package films 10 are provided, each of which is cut into adequate dimension corresponding to the size of the electrode material 1 which is to be packaged. The two package films 10 are laminated on each other with their innermost layers 14 opposed to each other. Next, the three sides of the laminated package films 10 are sealed by heating to form sealed side portions 19a, 19b and 19c. In this way, the bag 19 shown in FIG. 2 is obtained from the package films 10.

Then, the electrode material 1 is put in the bag 19, and the air in the bag 19 is displaced with a dry air. Then, the remaining side of the bag 19 is heat-sealed to form the sealed side portion 19d. Thanks to the moisture proof layer 12 in the package film 10, moisture can not enter the inside of the bag 19, of which the periphery is sealed. Thus, the humidity in the bag 19 can be prevented from increasing, where the electrode material 1 is packaged. Because of this function of the moisture proof layer in the package film 10, the electrode material 1 weak to moisture can be stored with keeping its performance.

Next, the conditions of the electrode material package 20 during transporting or storing are described.

In the package 20, the electrode material 1 is held between the pair of the flanges 22 Since the side face 22a of each of the flanges 22 is larger than the side face of the roll of the electrode material 1, the rolling of the electrode material 1 does not loose, or the wound layers in the rolling do not laterally slip into a conical winding. Besides, the roll of the electrode material 1 is protected from external impacts.

Further, thanks to the cushion material 22 held between the flanges 21 and the electrode material 1, the flanges 21 may not cause any damages on the electrode material 1 during the transportation.

The package films 10 for packaging the electrode material 1 have the moisture proof layer 12, and the innermost layers 14 of LLD-PEF of the package films 10 are sealed to each other at their periphery region to seal the bag 19. Thus, moisture can not enter the inside of the bag 19 made of the package film 10, so that the inner space of the bag 19 can be kept at a low humidity, where the electrode material 1 weak to moisture is packaged

During the transportation of the bag 19 enveloping the electrode material 1, the electrode material 1 may move in the bag 19. In such the case, because of the thick electrode material 1, the package film 10 of the bag 19 may be worn by the electrode material 1, or may be impacted by the electrode material 1. However, at inside of the moisture proof layer 12, the intermediate layer 13 made of the oriented nylon having flexibility and extensibility is provided, and this intermediate layer 13 can follow the movement of the electrode material 1 and simultaneously absorb the impacts. Therefore, pin holes hardly occur on the moisture proof layer 12 from the inside of the package film 10, so that the inside of the bag 19 made of the package film 10 can be kept in a low humidity condition.

Furthermore, the innermost layer 14 acting as a fused layer is thick enough to have sufficient adhesive strength. Therefore, pin holes are hard to occur in the sealed side portions 19a, 19b, 19c and 19d of the bag 19, even if the heavy electrode material 1 is packaged in the bag 19.

The concavity 21b is formed on the side face of the flange 21, which faces the package film 10, so as to receive therein the heads of the screws 31 which secure the flange 21 to the winding core 2. Therefore, the flange 21 can be firmly secured to the winding core 2, and the heads of the screws may not project from the flange 21 to damage the package film 10.

As has been described above, according to this embodiment, the electrode material 1 can be protected from damage due to external impacts or the like. Further, the occurrence of pin holes on the inner surface of the package film 10 due to the friction or impacts between the electrode material 1 and the bag 19 can be prevented, so that the electrode material 1 can be kept in a low humidity condition. Thus, the term over which the quality of the electrode material 1 is guaranteed can be prolonged.

Further, the package film 10 is manufactured from ordinary materials and by ordinary method, which are common to general lamination products. Thus, the production cost therefor does not become higher.

Further, the manufacturing costs for the cushion materials 22, the flanges 22 and the package film 10 used for packaging the electrode material 1 are not expensive. Thus, if these materials are utilized as disposable, the management cost can be reduced.

First Modification

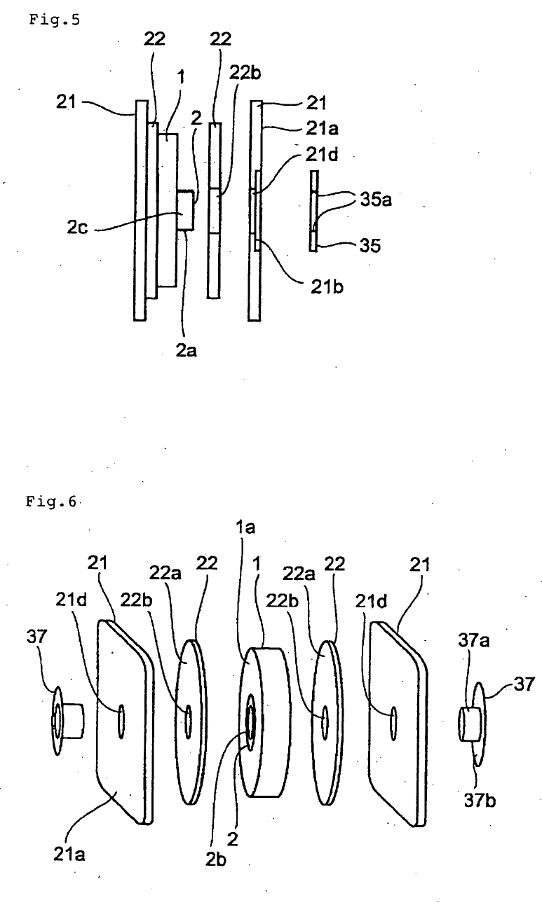

Hereinafter, a first modification of the present invention is described with reference to FIG. 5. The first modification shown in FIG. 5 is different only in the manner of securing the flange 21 to the winding core 2 compared with the first embodiment, and others are substantially the same as those in the first embodiment shown in FIGS. 1 to 4, and 9.

In FIG. 5, the like parts or components, which are the same as those in FIGS. 1 to 4, and 9, are denoted by the like reference numerals, to thereby skip the detailed descriptions thereof.

FIG. 5 shows the front view, illustrating how the cushion materials 22 and flanges 21 are attached to the electrode material 1.

As shown in FIG. 5, one of the flanges 21, for example at right side one, has a circular hole 21d at its center with an inner diameter substantially equal to the outer diameter of the projected portion 2c of the winding core 2. The projected portion 2c of the winding core 2, on which the electrode material 1 is wound, penetrates the hole 21d of the flange 21 and projects therefrom. On the outer surface of the projected portion 2c of the winding core 2, there is formed an outer thread 2a. On the other hand, a stopper ring 35 located at the outside of the flange 21 is provided with the inner thread 35a, which engages with the outer thread 2a formed on the projected portion 2c of the winding core 2. By engaging the inner thread 35a of the stopper ring 35 with the outer thread 2a of the projected portion 2c of the winding core 2, the stopper ring 35 is secured to the winding core 2 together with the flange 21 and the cushion material 22. In this way, the pair of flanges 21 can hold the electrode material 1 with the pair of cushion materials 22 therebetween.

In order to secure that the stopper ring 35 and the winding core 2 do not project beyond the side face 21a of the flange 21, it is preferable that a concavity 21b for receiving the stopper ring 35 is formed around the hole 21d on the side face 21a of the flange 21, and the length of the winding core 2 is so adjusted as not to project from the side face of the flange 21 (see FIG. 5).

Note that in FIG. 5 the flange 21 on the left side is secured to the winding core 2 in the same manner as the right side flange 21 in this FIG. 5, or the same manner as the embodiment shown in FIG. 4.

As described above, according to this modification, the flanges 21 can be reliably secured to the winding core 2.

Second Modification

A second modification of the present invention is described with reference to FIG. 6. This second modification is different only in the manner of securing the flanges 21 to the winding core 2 compared with the first embodiment, and others are substantially the same as those in the first embodiment shown in FIGS. 1 to 4, and 9.

The parts or components shown in FIG. 6 which are the same as those shown in FIGS. 1 to 4 and 9 are denoted by the same reference numerals, to thereby skip the detailed descriptions thereof.

FIG. 6 shows an exploded perspective, illustrating how the cushions 22 and the flanges 21 are attached to the electrode material 1.

As shown in FIGS. 6 and 9, the winding core 2, on which the electrode material 1 is wound, is cylindrically shaped and has a length equal to the width of the electrode material 1. A hole 21d is formed at the center of each of the flanges 21.

A core cap 37 is respectively disposed at the outsides of the flanges 21. Each of the core caps 37 has a cylindrical portion 37a, and a disc-shaped flange portion 37b on the outer end face of the cylindrical portion 37a. The outer diameter of the cylindrical portion 37a is smaller than the diameter of the hole 21d of the flange 21 and the diameter of the through hole 22b of the cushion material 22, and corresponds to the diameter of the center hole 2b of the winding core 2. On the other hand, the flange portion 37b has a diameter larger than the inner diameter of the hole 21d of the flange 21.

Each of the core caps 37 is engaged into the center hole 2b of the winding core 2, through the flange 21 and the cushion material 22. Thus, the core cap 37 is secured to the winding core 2, together with the flange 21 and the cushion material 22. In this way, the pair of the flanges 21 can hold the electrode material 1 with the pair of the cushion materials 22 therebetween.

As described above, according to this modification, the flanges 21 can be readily secured to the winding core 2.

### Second Embodiment

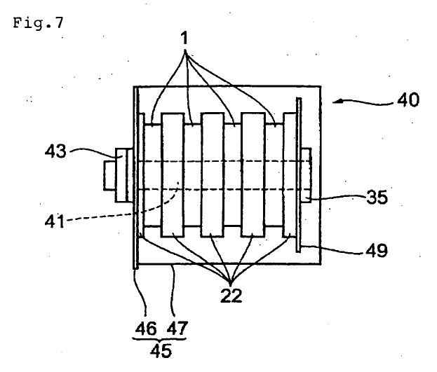

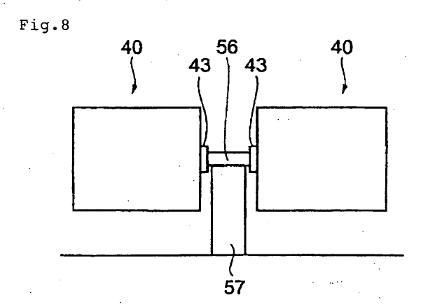

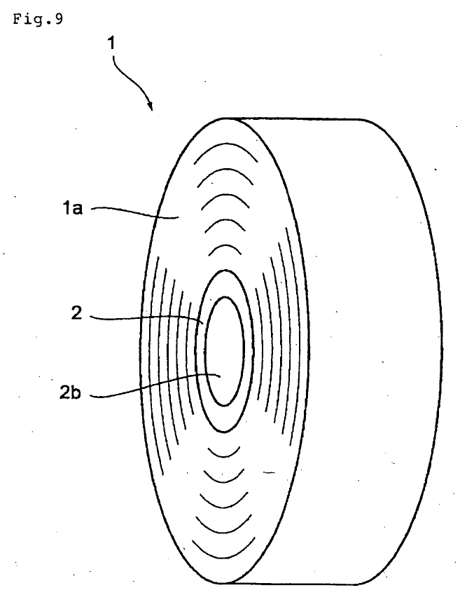

The second embodiment of the present invention is described with reference to FIGS. 7 and 8.

FIG. 7 shows an electrode material package 40 according to the present invention, and FIG. 8 shows a practical application of this package 40. In this embodiment, the like parts or components which correspond to those in the first embodiment shown in FIGS. 1 to 4 and 9 are denoted by the like reference numerals, to thereby skip the detailed descriptions thereof.

As shown in FIG. 7, the electrode material package 40 comprises a plurality of rolls of electrode materials 1, each obtained by winding the electrode material 1 onto a winding core 2; cushion materials 22 each interposed between the adjacent electrode materials 1; a skid shaft 41 which passes through the rolls of the electrode materials 1 and the cushion materials 22 to thereby support the same; and a casing 45 removably attached to the skid shaft 41.

The winding core 2, on which the electrode material 1 is wound, is cylindrically shaped and has a center hole 2b. The length of the winding core 2 is equal to the width of the electrode material 1 (see FIG. 9).

Next, the skid shaft 41 is described, which is passing through the rolls of the electrode materials 1 and the cushion materials 22. The skid shaft 41 is cylindrically shaped, which has an outer diameter substantially equal to the inner diameter of the center hole 2b of the winding core 2 and the inner diameter of the through hole 22a of the cushion material 22. The skid shaft 41 is made of a material such as stainless steel or the like.

On outer surface of one end of the skid shaft 41 (the right side in FIG. 7), there is formed an outer thread (not shown). This outer thread is engaged with an inner thread 35a formed to a stopper ring 35. The stopper ring 35 holds the cushion material 22 at the right most side through the flange 49. The other end of the skid shaft 41 (the left side in FIG. 7) is provided with a flange portion 43 having a larger outer diameter. This flange portion 43 may be formed integrally with the skid shaft 41, or may be separately formed and secured to the skid shaft 41.

In another embodiment, a tapped hole is formed in one end of the skid shaft (the right side in FIG. 7), and a plate (not shown) larger than the diameter of the through hole of the flange 49 for receiving the skid shaft is used, substituting for the stopper ring 35. The not shown plate is provided with a hole at its center for passing through a screw. With this screw, the skid shaft 41 and the not shown plate are fastened, so that the cushion material 22 on the right most side is held by the flange 49. In this case, it is not needed to provide the outer thread on one end of the skid shaft 41 (the right side in FIG. 7).

As described above, the stopper ring 35 holds the cushion material 22 at the right most side on the skid shaft 41 through the flange 49. The flange 49 is shaped in a circular plate, which has an outer diameter larger than the outer diameters of the roll of the electrode material 1 and the cushion material 22. At the center of the flange 49, there is formed a through hole (not shown), of which the inner diameter is substantially equal to the outer diameter of the skid shaft 41, for receiving the skid shaft 41 passing therethrough. The flange 49 is made of an aluminum plate, for example.

Next, the casing 45 having the moisture proof nature is described. The casing 45 is shaped in a square pillar, and comprises a casing body 47 and a lid 46, both of which are made of a moisture proof material such as aluminum. The casing body 47 and the lid 46 are removably connected to each other. When the lid 46 is attached to the casing body 47, the connected area therebetween is sufficiently sealed to shut out the moisture, to prevent the same from entering the casing 45.

The lid 46 is shaped in a flat rectangular plate, and has a through hole (not shown) at its center. This through hole has an inner diameter substantially equal to the outer diameter of the skid shaft 41, so that the skid shaft 41 can penetrate the through hole of the lid 46. As shown in FIG. 7, the flange portion 43 holds the cushion material 22 on the left most side on the skid shaft 41 through the lid 46. Thus, the electrode materials 1 and the cushion materials 22 are firmly held between the lid 46 and the flange 49, where the lid 46 functions as a kind of flange. The connected area between the casing body 47 and the lid 46 is sufficiently sealed to shut out the moisture, to prevent the same from entering the casing 45.

Further, a gasket is held between the lid 46 and the flange portion 43 in order to ensure the sealing. The lid 46 may be previously bonded to the flange portion 43 and the gasket.

Note that the shape of the casing 45 is not limited to the square pillar, and can be other polygonal pillar or a cylindrical one. Accordingly therewith, the shape of the lid 46 may be selected from other polygonal plates or a circular plate.

Next, the method for manufacturing the electrode material package 40 is described.

Firstly, the skid shaft 41 is passed through the plurality of the cushion materials 22 and the plurality of the rolls of the electrode materials 1, which are arranged alternately. Then, the flange 49 is mounted on the skid shaft 41, and the stopper ring 35 is engaged with the right end of the skid shaft 41. Next, the left end of the skid shaft 41 is passed through the lid 46, and the flange portion 43 is engaged thereto. Thus, the rolls of the electrode materials 1 and the cushion materials 22 are held between the lid 46 and the flange 49, on the skid shaft 41. After that, the rolls of the electrode materials 1 and the cushion materials 22 on the skid shaft 41 are set in the casing body 47, and the lid 46 is fixed to the casing body 47 to complete the electrode material package 40. Note that, when the lid 46 is fixed to the casing body 47, the air in the casing 45 is displaced with a dry air.

Next, the transportation or the storage of the packages arranged above is described.

The rolls of the electrode materials 1 and the cushion materials 22 on the skid shaft 41 are held between the lid 46 and the flange 49, both of which are larger than the side face la of the roll of the electrode material 1. Therefore, the rolling of the electrode material 1 does not loose, or the wound layers in the rolling do not laterally slip into a conical winding. Besides, the roll of the electrode material 1 is protected from external impacts.

Further, since the cushion materials 22 are disposed at both sides of the roll of the electrode material 1, the flange 49 and the lid 46 may not damage the electrode material 1 under the vibrations during transportation. Further, the mutual damaging of adjacent electrode materials 1 due to the friction therebetween can be prevented.

Further, the rolls of the electrode materials 1 held on the skid shaft 41 are sealed in the moisture proof casing 45, and the moisture can not enter the casing 45. That is, the electrode materials 1 weak to moisture can be stored under a low humidity atmosphere, provided that the internal atmosphere of the casing is previously displaced with a dry air. Furthermore, contact or impacts between the electrode materials 1 and an external object can be reliably prevented, so that the electrode materials 1 can be stored in safety.

As described above, according to this embodiment, the electrode materials 1 can be reliably protected from damage due to external impacts and so on. Further, the electrode materials 1 can be kept under a low humidity atmosphere. Thus, the term over which the quality of the electrode material 1 is guaranteed can be prolonged.

Further, since a plurality of the electrode materials 1 can be stored in one package, the labor effectiveness is improved, and the amount of discarded materials can be lowered.

Note that two electrode material packages 40 shown in FIG. 7 can be disposed while their skid shafts 41 are horizontally aligned, and these skid shafts 41 are joined by the connection 56, and this connection 56 is supported by a support member 57 (see FIG. 8). In this arrangement shown in FIG. 8, the electrode materials 1 can be easily secured on the skid shaft 41, and the casing body 47 can be easily attached to the lid 46.

### Third Embodiment

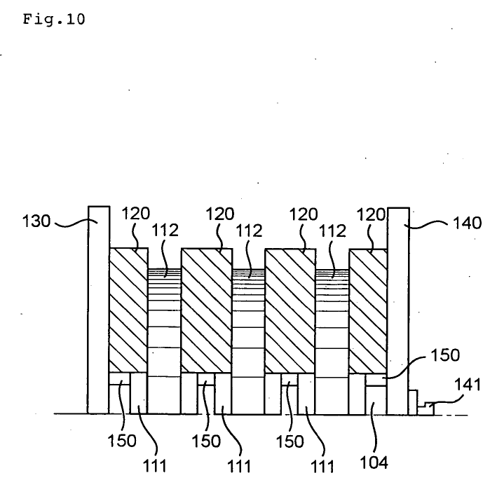

The third embodiment of the present invention is described with reference to FIGS. 10 to 13. The third embodiment is mainly intended to prevent a lateral slip in the wound layers of the electrode material on the winding core.

<<Principle for Preventing the Lateral Slip>>

FIG. 10 shows the enlarged view of a main part, wherein only some elements are shown in cross section, illustrating the principle to prevent the lateral slip in the wound layers of the electrode material in the third embodiment. FIG. 10 corresponds to the inside of the casing shown in FIG. 7. In FIG. 10, in order to clearly illustrate the principle, the cushion materials 120 are shown in cross section. In the shown embodiment, three rolls 110 of electrode material are supported on a support shaft (skid shaft) 104. However, the number of the rolls 110 is not limited, and one roll or a plurality of rolls may be supported on the support shaft 104.

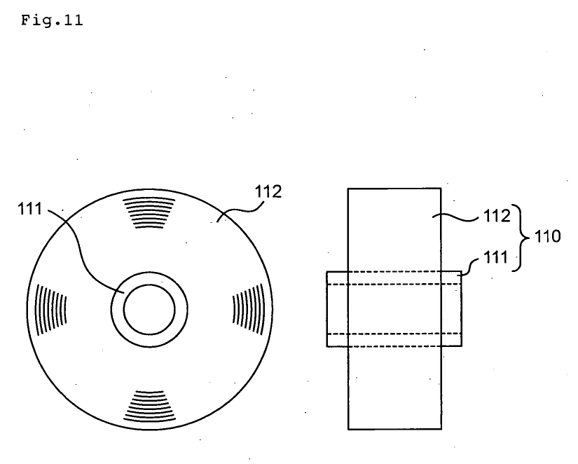

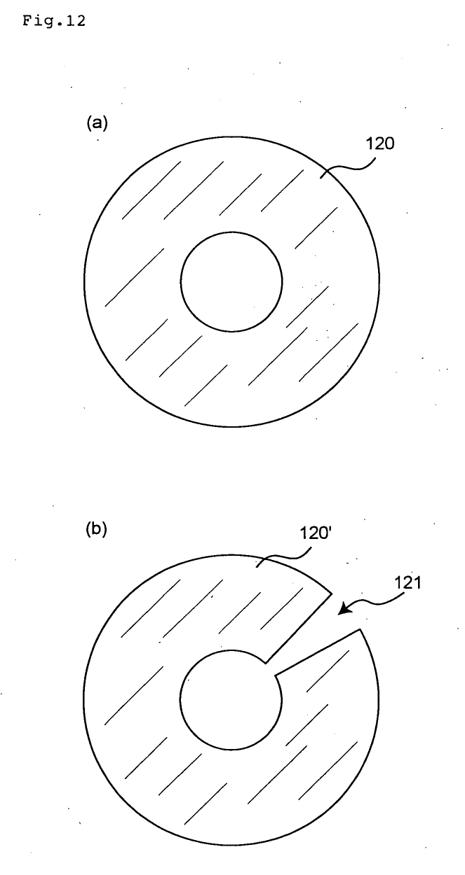

As shown in FIG. 11, the roll 110 comprises a hollow cylindrical core 111 and the wound layers 112 of a continuous sheet, which is wound on the core 111. The core 111 laterally projects from both sides of the wound layers 112.

In FIG. 10, all of the rolls 110 are held by a base plate 130 and an end plate 140 in pressing manner from laterally outsides, with the cushion materials 120 located between the rolls 110. Further, the cushion materials 120 are also provided between the base plate 130 and the roll 110, and between the end plate 140 and the roll 110, respectively.

A screw 141 is engaged to the end face of the support shaft 104. Tightening up the screw 141, the end plate 140 compresses the cushion materials 120 and the rolls 110 toward the base plate 130.

As is understood from FIG. 10, the base plate 130 and the end plate 140 extend from the support shaft 4, to the extent larger than the radius of the roll 110. The cushion materials 120 is disposed facing to only the wound layers 112 of the roll 110, but not facing to the core 111 of the roll 110.

Further, the thickness of the cushion materials 120 along the support shaft 104 is so selected that spaces 150 can be kept between the cores 111 of the rolls, between the base plate 130 and the core 111, and between the end plate 140 and the core 111, respectively.

Thanks to the arrangement as described above, the compressing forces from the base plate 130 and the end plate 140 are effectively applied to whole side faces of the wound layers 112 of the rolls 110 through the cushion materials 120, avoiding the cores 111 of the rolls 110. In other words, the compressing force acts on whole side faces of the wound layers 112 of the rolls 110, but does not act on the cores 111.

If the compressing force also acts on the cores 111 of the rolls, the compressing force on the core 111 and the compressing force on the wound layers 112 are not equal to each other. As a result, a lateral slip in the wound layers 112 on the core 111 would easily occur at near the connected region between the core 111 and the wound layers 112 (i.e., near the outer surface of the core 111).

The arrangement of the third embodiment makes it possible to effectively prevent such the lateral slip in the wound layers on the core 111, because the compressing force does not act on the core 111.

To achieve the above effect, it is necessary that the cushion materials 120, the base plate 130 and the end plate 140 should extend at least equal to the outer diameter of the roll 110, or larger.

In the embodiment shown in FIG. 10, the spaces 150 are formed between the cores 111 of the rolls, between the base plate 130 and the core 111, and between the end plate 140 and the core 111, without exception. Such spaces 150 are not necessarily formed at all the above interfaces. The effect of preventing the lateral slip in the wound layers may be achieved, provided that a space 150 is formed at least one interface. However, it is preferable to form the spaces 150 at all of the interfaces as described above.

<<Shape of Cushion Material>>

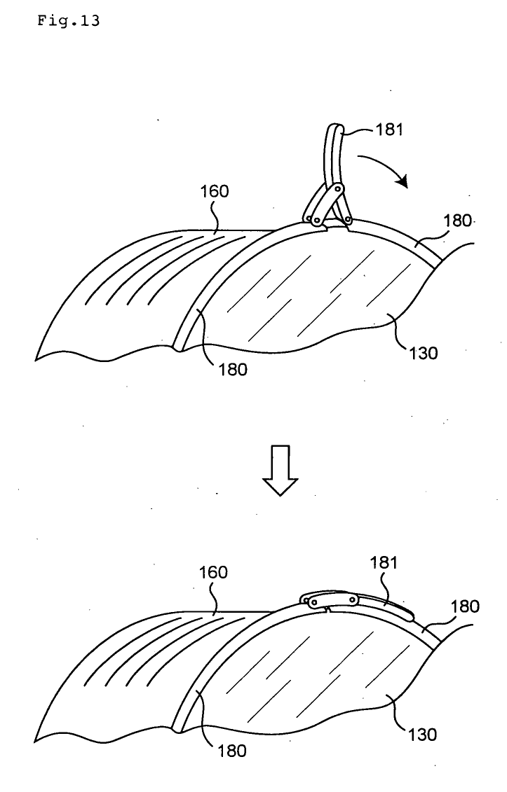

There is no particular limit in selection of the shape and material of the cushion material 120, in so far as it can cover a whole of the side face of the wound layers 112 of the roll 110 to thereby prevent the lateral slip in the wound layers on the core 111. For example, as shown in FIG. 12(a), the cushion material may be a thin annular plate made of foamed polyethylene. A proper number of such the cushion materials can be laminated and disposed at a suitable position. In addition, the number of such the cushion materials may be conveniently selected to adjust the thickness of the lamination.

In the third embodiment, there exist the spaces 150 as described above. Thus, in order to visually observe the spaces 150 from outside, it is preferable to use the cushion material 120′, which is provided with the cutout portion 121 as shown in FIG. 12(b). Through such the cutout portion 121, one can visually check from outside, whether the spaces 150 are appropriately kept, or not.

<<Transparent Cover>>

In the case that the continuous sheet composing the wound layers 112 of the roll 110 is a material weak to moisture (e.g., an electrode material for batteries), it is desirable to cover each of the supported rolls 110 with a sealing cover. In the third embodiment, a transparent cover 160 is connected to the base plate 130 to achieve the sealing (see FIG. 13). The transparent cover 160 may be of the same shape as that of the casing body 47 shown in FIG. 7, or may be of other shape.

Since the cover 160 is transparent, the inside of which can be seen from outside. Thus, a humidity indicator is placed inside the cover, and one can visually check from outside, whether a desirable humidity for the packaged material is maintained, or not. The humidity indicator itself may be any of known ones, and the detailed explanation is not made, which can visually indicate the ambient humidity.

If the material to be packaged requires a predetermined ambient temperature, it is possible to place a thermometer in the transparent cover 160 and to check the temperature from outside by visual observation.

Further, in the case that the spaces 150 is formed and the cushion materials 120′ having the cutout portion 121 are used, it is possible to visually check, through the transparent cover 160, whether or not the spaces 150 are appropriately ensured.

<<Connection Ring>>

The transparent cover 160 is connected to the base plate 130 at their peripheral edge to thereby be secured to the base plate 130, and a sealed space is formed therein. To facilitate this connection, preferably, a connection ring 180 as shown in FIG. 13 is used. FIG. 13 shows the partial perspective seen from the rear side of the base plate 130, showing the connection between the transparent cover 160 and the base plate 130.

Firstly, the peripheral edges of the transparent cover 160 and the base plate 130 are brought into contact with each other. Then, the connection ring 180 is disposed to cover overall of the contacted peripheral edges. After that, the lever member 181 is rotated downward to tightening up the connection ring 180, to complete the connecting operation.

Note that appropriate sealing materials may be preferably applied between the contacted peripheral edges of the transparent cover 160 and the base plate 130, or on the inner surface of the connection ring 180.

The packages would be conveniently stored or transported, if the support shafts 104 of the packages described in the third embodiment are horizontally supported by the stand as shown in FIG. 8.

1-16. (canceled)

17. A package film for packaging an electrode material, characterized in that the package film comprises:
a moisture proof layer of an aluminum foil, and an intermediate layer of an oriented nylon, which is located inside of the moisture proof layer and faces the electrode material.

18. The package film of claim 17, further comprising an outermost layer of PET and an innermost layer of LLD-PEF.

19. An electrode material package, characterized in that it comprises:
a roll of an electrode material which is wound onto a winding core,
a pair of flanges which hold both sides of the roll of the electrode material through a pair of cushion materials, and which have a side face larger than a contour of the roll of the electrode material, and
a package film which packages the roll of the electrode material,
the package film comprising a moisture proof layer of an aluminum foil, and an intermediate layer of an oriented nylon, which is located inside of the moisture proof layer and faces the electrode material.

20. The electrode material package of claim 19, characterized in that:
the winding core, on which the roll of the electrode material is wound, is secured to the flange with screws, so that the pair of flanges hold the roll of the electrode material.

21. The electrode material package of claim 19, characterized in that:
the winding core, on which the roll of the electrode material is wound, is projected from the roll of the electrode material to pass through the flange, and
the projected portion of the winding core is provided with an outer thread, with which a stopper ring is engaged, so that the pair of flanges hold the roll of the electrode material.

22. The electrode material package of claim 19, characterized in that:
the winding core, on which the roll of the electrode material is wound, has a center hole extending along its longitudinal axis,
a pair of core caps are provided on outer sides of the pair of flanges, each of the core caps passing through the flange to engage with the center hole of the winding core, and
each of the core caps is engaged into the center hole of the winding core through the flange, so that the pair of flanges hold the roll of the electrode material.

23. An electrode material package, characterized in that it comprises:
a plurality of rolls of electrode materials, each of which is wound onto a winding core,
cushion materials, each of which is interposed between the rolls of the electrode materials,
a skid shaft which passes through the winding cores, on each of which the roll of the electrode material is wound, and the cushion materials to thereby support them thereon, and
a moisture proof casing, which encloses the rolls of the electrode materials and the cushion materials, and is removably attached to the skid shaft.

24. The electrode material package of claim 23, further comprising:
a pair of flanges which hold the rolls of the electrodes and the cushion materials, and each of which has a larger side face than a contour of the roll of the electrode material.

25. The electrode material package of claim 23, characterized in that:
one end portion of the skid shaft is enclosed in the casing, and the other end portion of the skid shaft is projected out of the casing,
the one end portion of the skid shaft is engaged with a stopper ring, and the other end portion of the skid shaft is provided with a flange portion, so that the rolls of the electrode materials are held between the flange portion of the skid shaft and the stopper ring.

26. The electrode material package of claim 23, characterized in that:
the casing comprises a casing body and a lid fixed to the skid shaft.

27. The electrode material package of claim 24, characterized in that:
the casing comprises a casing body and a lid fixed to the skid shaft, and
the lid functions as one of the pair of the flanges.

28. An electrode material package, characterized in that it comprises:
a support shaft for supporting one or more rolls, each of which comprises a hollow cylindrical core and wound layers of a continuous sheet wound thereon, the support shaft passing through the hollow cylindrical core of the roll,
a base plate which extends from the support shaft to the extent larger than a radius of the roll, and which supports a whole side face of the wound layers of the continuous sheet through a cushion material,
an end plate which extends from the support shaft to the extent larger than the radius of the roll, and which supports a whole side face of the wound layers of the continuous sheet through a cushion material, and presses the same toward the base plate,
a cushion material, which is provided when two or more of the rolls are provided, and which is compressed between the whole side faces of the wound layers of adjacent rolls, and
a cover which covers the rolls supported on the support shaft,
the thickness of the cushion materials in the longitudinal direction of the support shaft being selected, so that at least one space can be formed, between the core of the roll and the base plate, between the core of the roll and the end plate, and between the cores of the adjacent rolls if two or rolls are provided.

29. The electrode material package of claim 28, characterized in that:
the cover is a transparent cover, which is connected to the peripheral edge of the base plate to seal the roll supported on the support shaft.

30. The electrode material package of claim 29, characterized in that:
an annular connection ring is further provided, which tightens up the peripheral sides of the transparent cover and the base plate to connect them, and
the connection ring is provided with a lever member with which the tightening up operation can be competed in one-touch.

31. The electrode material package of claim 28, characterized in that:
the cushion material is provided with a cutout portion through which the space can be confirmed from outside.

32. The electrode material package of claim 31, characterized in that:
the cover is a transparent cover, which is connected to the peripheral edge of the base plate to seal the roll supported on the support shaft.

33. The electrode material package of claim 32, characterized in that:
an annular connection ring is further provided, which tightens up the peripheral sides of the transparent cover and the base plate to connect them, and
the connection ring is provided with a lever member with which the tightening up operation can be competed in one-touch.

34. A stand for a package, comprising one of the electrode material packages of claims 28 to 33.
